(19) United States
(12) Patent Application Publication
(10) Pub. No.: US 2012/0269006 A1
(43) Pub. Date: Oct. 25, 2012

(54) SEMICONDUCTOR DEVICE

(75) Inventor: Jin Chul PARK, Gyeonggi-do (KR)

(73) Assignee: Hynix Semiconductor Inc., Icheon (KR)

(21) Appl. No.: 13/326,240

(22) Filed: Dec. 14, 2011

(30) Foreign Application Priority Data
Apr. 25, 2011 (KR) 10-2011-0038557

(51) Int. Cl. H01L 23/48; G11C 7/10; G11C 7/06; H01L 27/105; G11C 8/00

(52) U.S. Cl. 365/189.05; 257/763; 257/750; 257/296; 365/230.01; 365/205; 257/E23.01; 257/E27.081

(57) ABSTRACT

A semiconductor device is capable of reducing the coupling capacitance between adjacent bit lines by forming an air-gap at an opposite side of a one side contact when forming a buried bit line or increasing a thickness of an insulating layer, thereby improving characteristics of the semiconductor devices. The semiconductor device includes a plurality of line patterns including one side contacts, a bit line buried in a lower portion between the line patterns, a bit line junction region formed within each of the line patterns at one side of the bit line, and an air-gap formed between the other side of the bit line and each of the line patterns.

### CROSS-REFERENCES TO RELATED APPLICATION

The present application claims priority to Korean patent application number 10-2011-0038557 filed on 25 Apr. 2011, which is incorporated by reference in its entirety.

### BACKGROUND OF THE INVENTION

1. Technical Field

The inventive concept relates to a semiconductor device, and more particularly, to a semiconductor device having a buried bit line.

2. Related Art

As the integration degree of semiconductor devices is increased, channel lengths of transistors are gradually reduced. However, the reduction of the channel lengths of the transistors causes short channel effects such as drain induced barrier lowering (DIBL), a hot carrier effect, and punch-through. To solve this problem, various methods such a method of reducing a depth of a junction region or a method of relatively increasing a channel length by forming a recess in a channel region of a transistor have been suggested.

However, as the integration density of the semiconductor memory devices, for example, dynamic random access memories (DRAMs) increases, fabrication of transistors having a smaller size is demanded. Accordingly, it is difficult to satisfy the desired device dimension with a current planar transistor structure in which a gate electrode is formed over a semiconductor substrate and junction regions are formed at both sides of the gate electrode even when scaling the channel length. To solve this problem, a vertical channel transistor structure has been suggested.

In recent years, there is a problem in that coupling capacitance between bit lines is increased since a buried bit line interferes with a bit line junction region due to reduction of a device size when the vertical channel transistor structure is formed. Thus, when a given buried bit line is activated, another buried bit lines neighboring the given bit line may also be activated, resulting in leakage. The leakage serves as a noise and prevents a proper readout of data.

### SUMMARY

According to one aspect of an exemplary embodiment, a semiconductor device includes a plurality of line patterns including one side contacts (OSCs), a bit line buried in a lower portion between the line patterns, a bit line junction region formed within each of the line patterns at one side of the bit line, and an air-gap formed between the other side of the bit line and each of the line patterns.

The line patterns may be etched portions of a semiconductor substrate. The semiconductor device may further include a liner insulating layer on surfaces of the line patterns. The bit line may include any one selected from the group consisting of a titanium (Ti) layer, a titanium nitride (TiN) layer, a doped polysilicon layer and a combination thereof.

The bit line junction region may be connected to the bit line through the OSC. The air-gap may be formed at side of the bit line and an insulating layer may be buried within the air-gap.

The semiconductor device may further include a capping layer on the bit line including the air-gap. The capping layer may include a nitride layer.

According to another aspect of an exemplary embodiment, a semiconductor cell includes a transistor including a gate and a storage node junction region and a bit line disposed to intersect the gate, one side of the bit line connected to a bit line junction region. An air-gap is formed between the other side of the bit line and each of line patterns.

The semiconductor cell may further include a storage unit connected to the storage node junction region. The storage unit may include a capacitor.

The gate may be a vertical gate formed at both sides of a plurality of pillar patterns which are etched upper portions of the line patterns. The bit line may include any one selected from the group consisting of a Ti layer, a TiN layer, a doped polysilicon layer and a combination thereof.

The air-gap may be formed at side of the bit line and an insulating layer is buried within the air-gap.

According to another aspect of an exemplary embodiment, a semiconductor device includes a core circuit area and a semiconductor cell array. The semiconductor cell array includes a transistor including a vertical gate and a storage node junction region, a capacitor connected to the storage node junction region, and a bit line disposed to intersect the vertical gate, one side of the bit line connected to a bit line junction region. An air-gap is formed between the other side of the bit line and each of pillar patterns.

The core circuit area may include a row decoder which selects one of word lines of the semiconductor cell array, a column decoder which selects one of bit lines of the semiconductor cell array, and a sense amplifier which senses data stored in a semiconductor cell selected by the row decoder and the column decoder.

According to another aspect of an exemplary embodiment, a semiconductor module includes a semiconductor device and an external input/output (I/O) line. The semiconductor device includes a semiconductor cell array, a row decoder, a column decoder, and a sense amplifier. The semiconductor cell array includes a transistor including a vertical gate and a storage node junction region, a capacitor connected to the storage node junction region, a bit line disposed to intersect the vertical gate, one side of the bit line connected to a bit line junction region, and an air-gap formed between the other side of the bit line and each of pillar patterns.

The semiconductor device may further include a data input buffer, a command/address input buffer, and a resistor unit. The semiconductor module may further include an internal command/address bus which transmits a command/address signal to the command/address input buffer, and a resistor unit.

The external I/O line may be electrically connected to the semiconductor device.

According to another aspect of an exemplary embodiment, a semiconductor system including a plurality of semiconductor modules and a controller which communicates data and command/address with the semiconductor module. Each of the plurality of semiconductor modules includes a semiconductor device, a command link, and a data link. The semiconductor device includes a semiconductor cell array, a row decoder, a column decoder, and a sense amplifier. The semiconductor cell array includes a transistor including a vertical gate and a storage node junction region, a capacitor connected to the storage node junction region, a bit line disposed to intersect the vertical gate, one side of the bit line connected to a bit line junction region, and an air-gap formed between the other side of the bit line and each of pillar patterns.

According to another aspect of an exemplary embodiment, a method of manufacturing a semiconductor device includes forming line patterns by etching a semiconductor substrate, burying a bit line in a lower portion between the line patterns, forming a bit line junction region in each of line patterns at the other side of the bit line, and forming an air-gap between one side of the bit line and each of line patterns.

The method may further, after the forming the line patterns, include forming a first liner insulating layer on surfaces of the line patterns.

The forming the bit line may include forming a first bit line conduction layer in a lower portion between the line patterns, forming a second bit line conduction layer on the first bit line conduction layer, forming a sacrificial conduction layer on a surface of each of the line patterns at one side of the second bit line conduction layer, and forming a third bit line conduction layer on the second bit line conduction layer in which the sacrificial conduction layer is formed.

The forming the second bit line conduction layer may include forming a polysilicon layer on the first bit line conduction layer, forming a second liner insulating layer on the first liner insulating layer exposed on the polysilicon layer, and etching the polysilicon layer to expose the first liner insulating layer below the second liner insulating layer. The bit line may include any one selected from the group consisting of a Ti layer, a TiN layer, a doped polysilicon layer and a combination thereof.

The forming the sacrificial conduction layer on the surface of each of the line patterns at one side of the second bit line conduction layer may include forming a TiN layer of a sidewall of each of the line patterns on the second bit line conduction layer, burying an insulating layer between the line patterns on which the TiN layer is formed, and removing a portion of the titanium nitride layer on the surface of each of the line patterns at the other side of the second bit line conduction layer.

The removing the portion of the TiN layer on the surface of each of the line patterns at the other side of the second bit line conduction layer may include forming a mask pattern exposing the portion of the TiN layer on the surface of each of the line patterns at the other side of the second bit line conduction layer, implanting ions into the TiN layer using the mask pattern as a mask through a tilted ion implantation process, and removing an ion-implanted portion of the TiN layer to expose the first liner insulating layer.

The method may further, after removing the ion-implanted portion of the titanium nitride layer, include forming a one side contact exposing each of the line patterns by removing the exposed first liner insulating layer. The forming the air-gap may further, after the forming the third bit line conduction layer, include forming a capping layer on surfaces of the third bit line conduction layer, the sacrificial conduction layer, and the second liner insulating layer, and removing the sacrificial conduction layer.

The method may further, after removing the sacrificial conduction layer, include burying an insulating layer within the air-gap. The method may further, after the removing the sacrificial conduction layer, include further etching the bit line exposed by the air-gap.

These and other features, aspects, and embodiments are described below in the section entitled “DESCRIPTION OF EXEMPLARY EMBODIMENT”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a view illustrating a semiconductor device according to an exemplary embodiment of the present invention, wherein (i) is a perspective view of a semiconductor device, (ii) is a cross-sectional view of the semiconductor device taken along the line X-X′ of (i), and (iii) is a cross-sectional view of the semiconductor device taken along the line Y-Y′ of (i);

FIGS. 2A to 2M are views illustrating a method of manufacturing a semiconductor device according to an exemplary embodiment of the present invention, wherein (i) is a perspective view of a semiconductor device, (ii) is a cross-sectional view of the semiconductor device taken along the line X-X′ of (i), and (iii) is a cross-sectional view of the semiconductor device taken along the line Y-Y′ of (i);

FIGS. 3A to 3D are views illustrating a method of manufacturing a semiconductor device according to another exemplary embodiment of the present invention, wherein (i) is a perspective view of a semiconductor device, (ii) is a cross-sectional view of the semiconductor device taken along the line X-X′ of (i), and (iii) is a cross-sectional view of the semiconductor device taken along the line Y-Y′ of (i);

FIG. 4 is a circuit diagram illustrating a semiconductor cell array according to an exemplary embodiment of the present invention;

FIG. 5 is a block diagram illustrating a semiconductor device according to an exemplary embodiment of the present invention;

FIG. 6 is a block diagram illustrating a semiconductor module according to an exemplary embodiment of the present invention; and

FIG. 7 is a block diagram illustrating a semiconductor system according to an exemplary embodiment of the present invention.

### DESCRIPTION OF EXEMPLARY EMBODIMENT

Exemplary embodiments are described herein with reference to cross-sectional illustrations that are schematic illustrations of the embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein, but may include deviations in shapes that result, for example, from manufacturing. In the drawings, lengths and sizes of layers and regions may be exaggerated for clarity. Where possible, like reference numerals in the drawings denote like elements. It is also understood that when a layer is referred to as being “on” another layer or substrate, it can be directly on the other or substrate, or intervening layers may also be present.

Hereinafter, semiconductor devices according to exemplary embodiments of the present invention will be described in detail with reference to accompanying drawings.

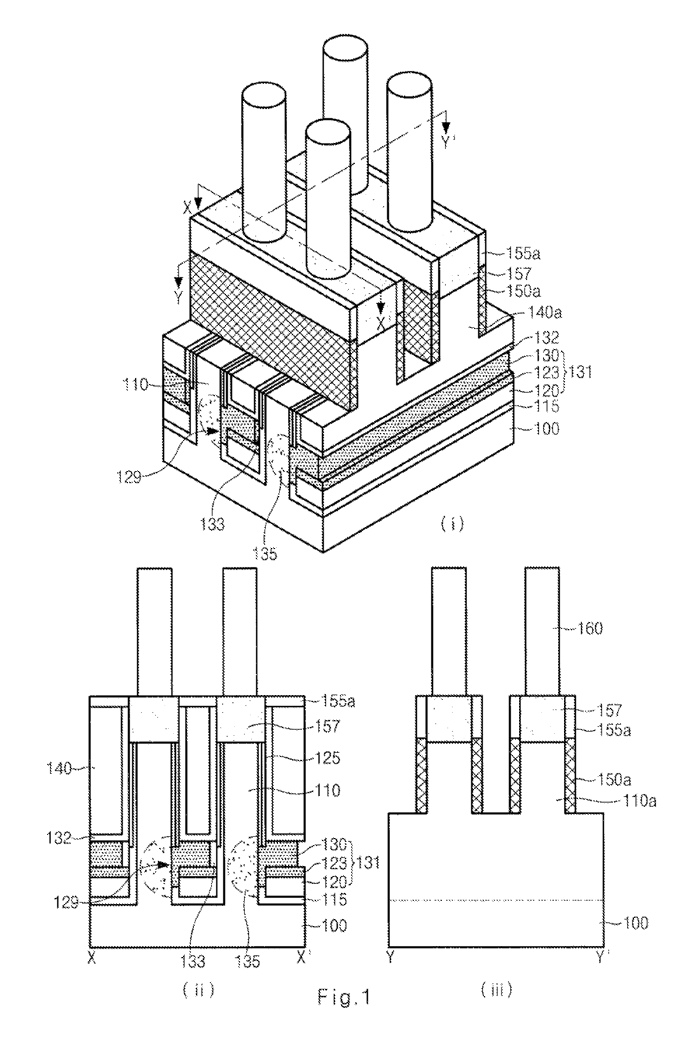

FIG. 1 is a view illustrating a semiconductor cell including a bit line according to an exemplary embodiment of the present invention, wherein (i) is a perspective view of a semiconductor cell, (ii) is a cross-sectional view of the semiconductor cell taken along the line X-X′ of (i), and (iii) is a cross-sectional view of the semiconductor cell taken along the line Y-Y′ of (i).

Referring to FIG. 1, the semiconductor cell includes a bit line including an air-gap to enhance insulation between a bit line and a bit line junction region coupled to a neighboring bit line, between a gate and a bit line, and between a junction region and a storage unit. Elements of such a semiconductor cell will be described in detail later.

First, a plurality of line patterns 110, each including one side contact (OSC) 129, are formed over a semiconductor substrate 100. The OSC 129 is defined by a first liner insulating layer 115 and a second liner insulating layer 125 formed over a sidewall of the line patterns 110. The first liner insulating layer 115 may include an oxide layer and the second liner insulating layer 125 may include a nitride layer.

A bit line 131 is formed in a lower portion between the line patterns 110. At this time, the bit line 131 may include a first bit line conduction layer 120, a second bit line conduction layer 123 and a third bit line conduction layer 130. The first, the second and the third bit line conduction layers 120, 123 and 130 may include a titanium (Ti) layer, a titanium nitride (TiN) layer, a doped polysilicon layer, or a combination thereof. More preferably, the first bit line conduction layer 120 may include a Ti layer, a TiN layer, or a combination thereof. The second and the third bit line conduction layers may include doped polysilicon layers, respectively. The first bit line conduction layer 120 is formed to reduce resistance of the bit line 131.

A bit line junction region 135 is disposed at a first sidewall of the line patterns 110 coupled to the first sidewall of the bit line 131. An air-gap 133 is formed between a second sidewall of the bit line 131 and a second sidewall of the line patterns 110. The air-gap 133 enhances insulation between the bit line 131 and the bit line junction region 135 coupled to a neighboring bit line 131, thereby reducing coupling capacitance between the bit line 131 and the bit line junction region 135. In an embodiment, ar-gap 133 is larger than the size shown in FIG. 1. An insulating layer may be additionally formed within the air-gap 133.

A gate 150a extending across the bit line 131 is formed over the bit line 131. Gates 150a are formed at both sides of pillar patterns 110a. Thus, the gate 150a connects a plurality of pillar patterns 110a to each other. A storage node junction region (not shown) is formed in an upper portion of each of the pillar patterns 110a and a storage unit 160 is disposed on each of the pillar patterns 110a to be connected to the storage node junction region. Here, the storage unit 160 may include a capacitor.

As described above, the air-gap or the additional insulating layer is disposed at the second sidewall of the bit line, that is, at an opposite side to the OSC 129, and increases insulation between the bit line 131 and the bit line junction region 135 coupled to a neighboring bit line 131. Thereby, coupling capacitance between the buried bit line 131 and the bit line junction region 135 can be reduced.

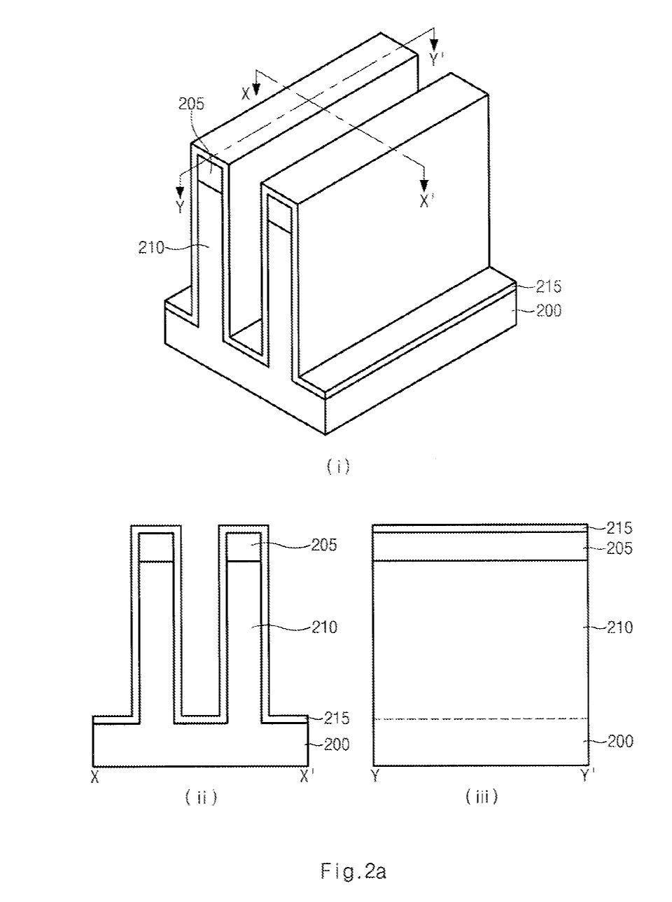

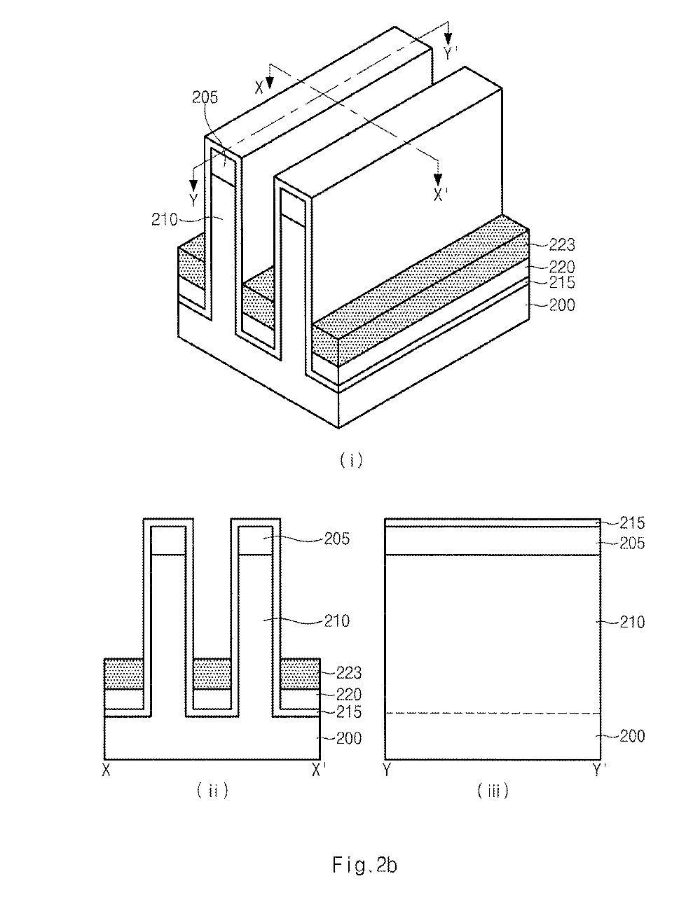

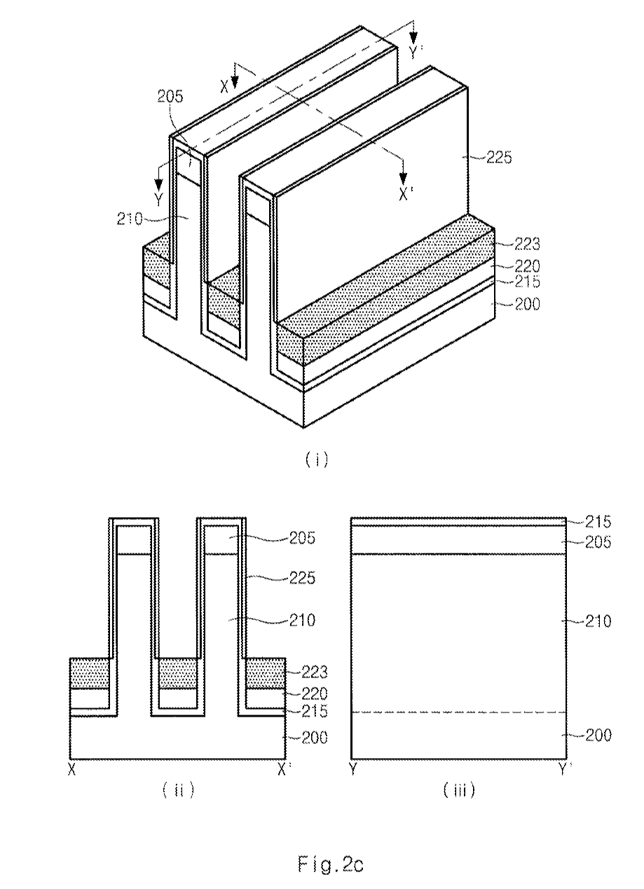

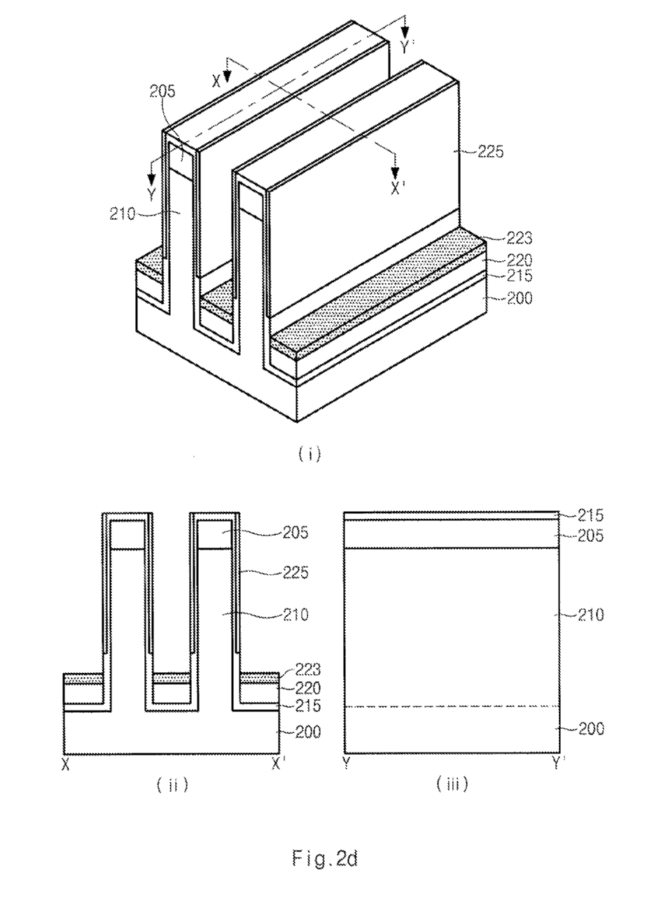

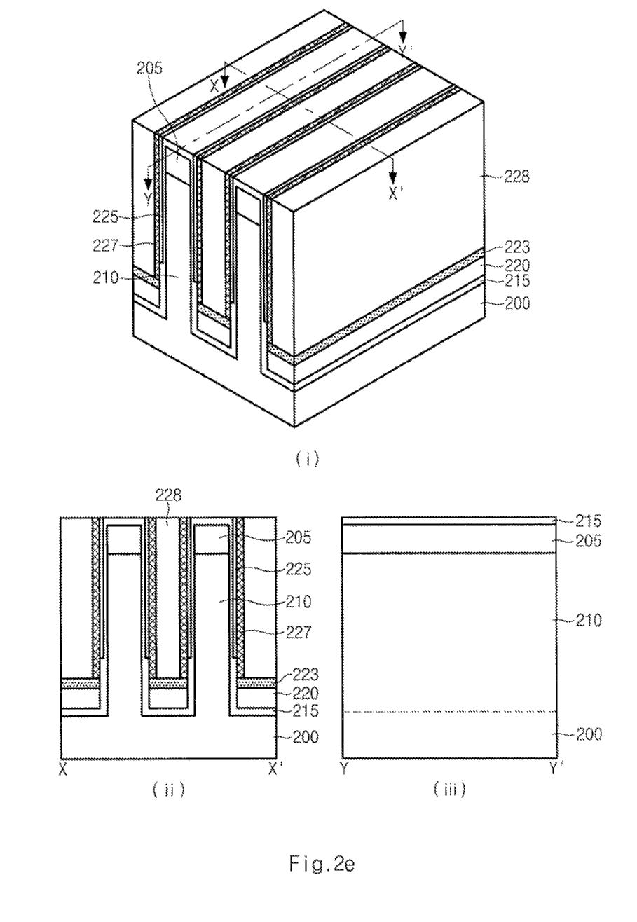

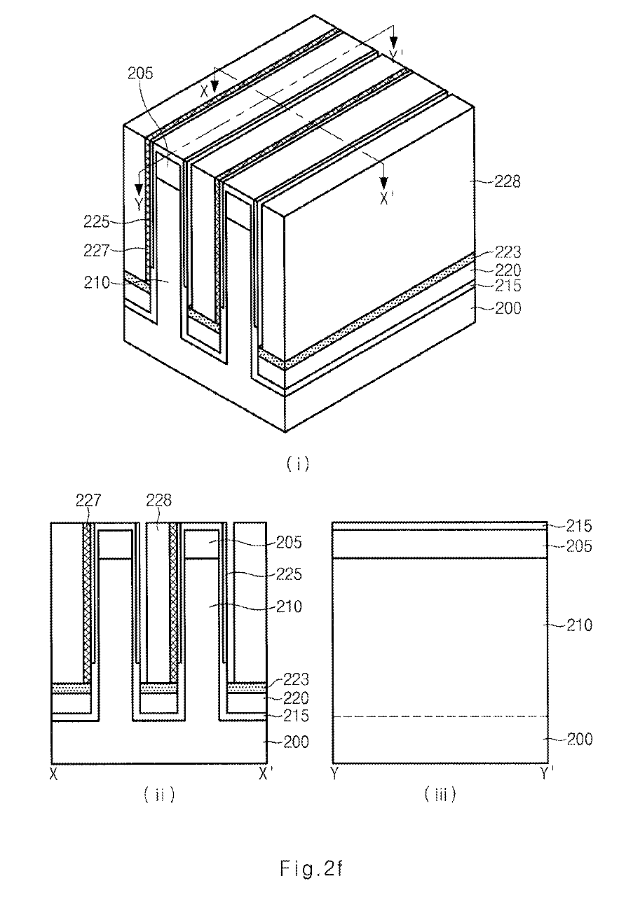

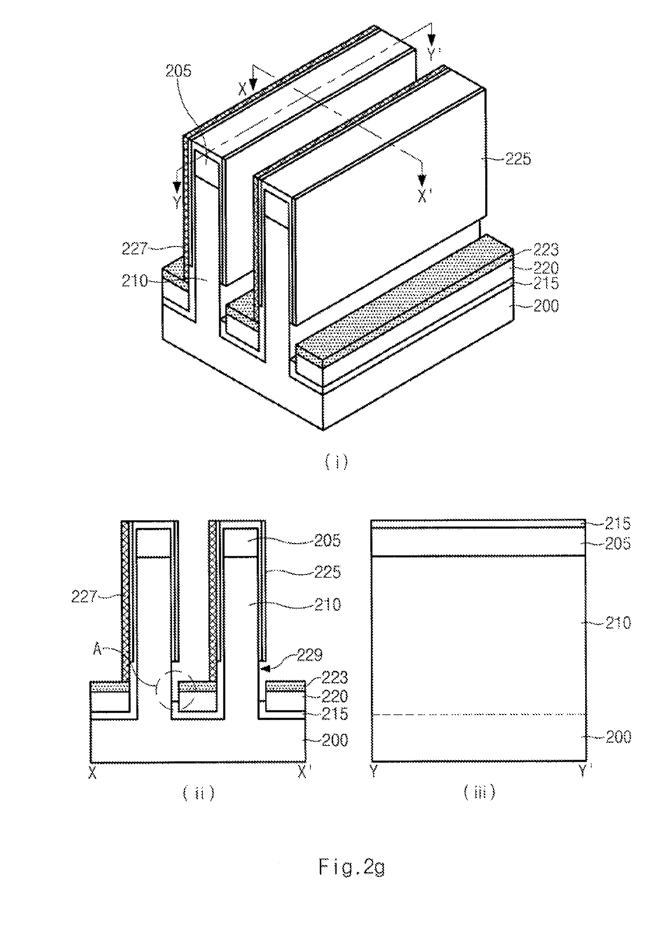

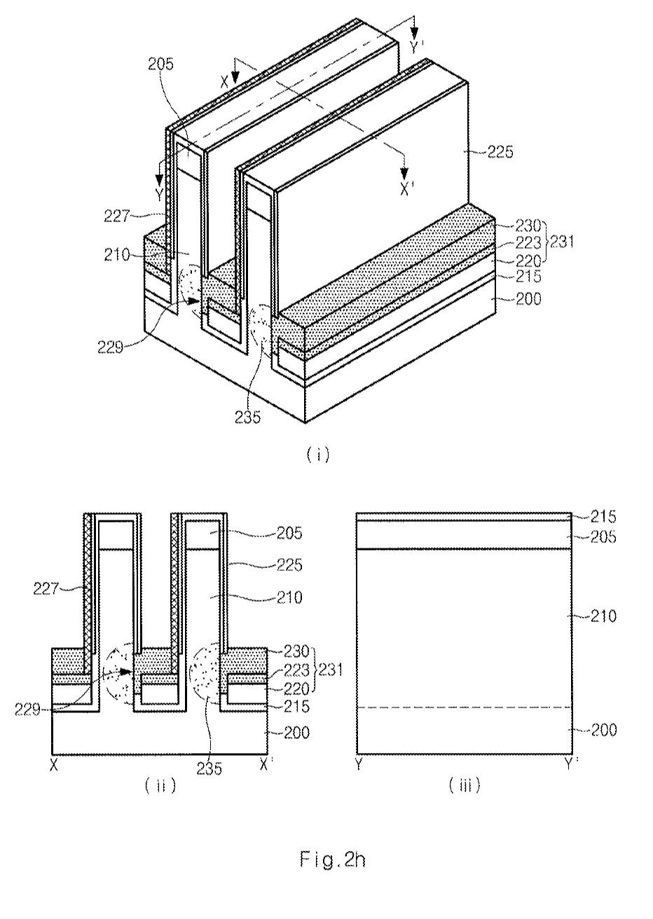

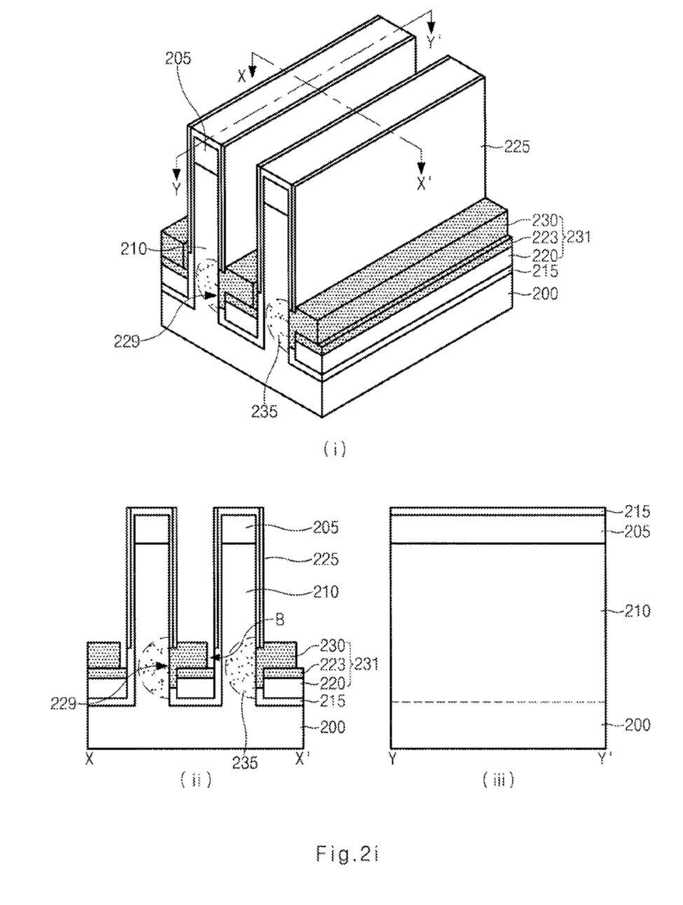

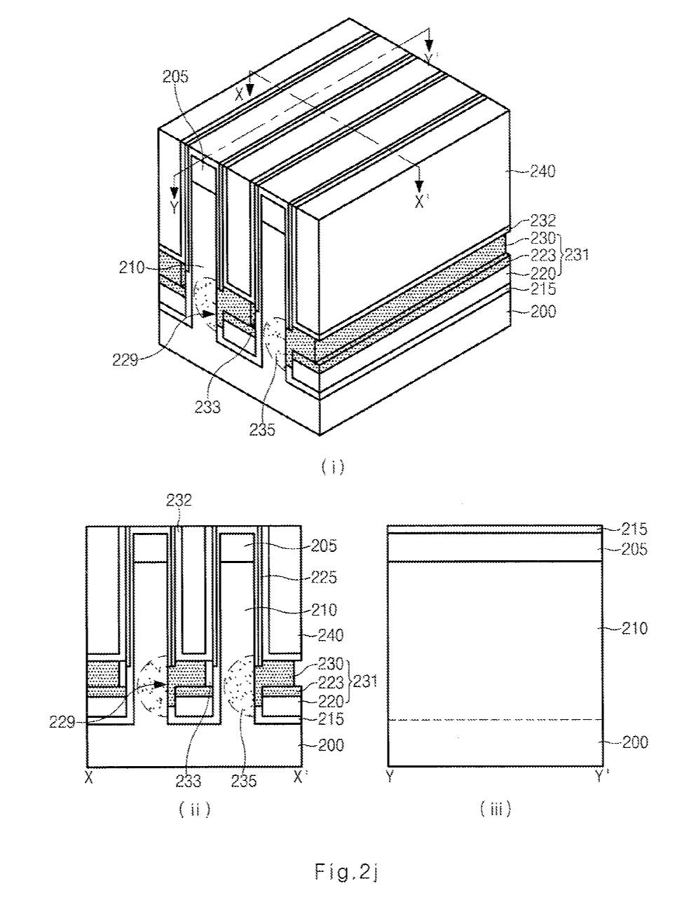

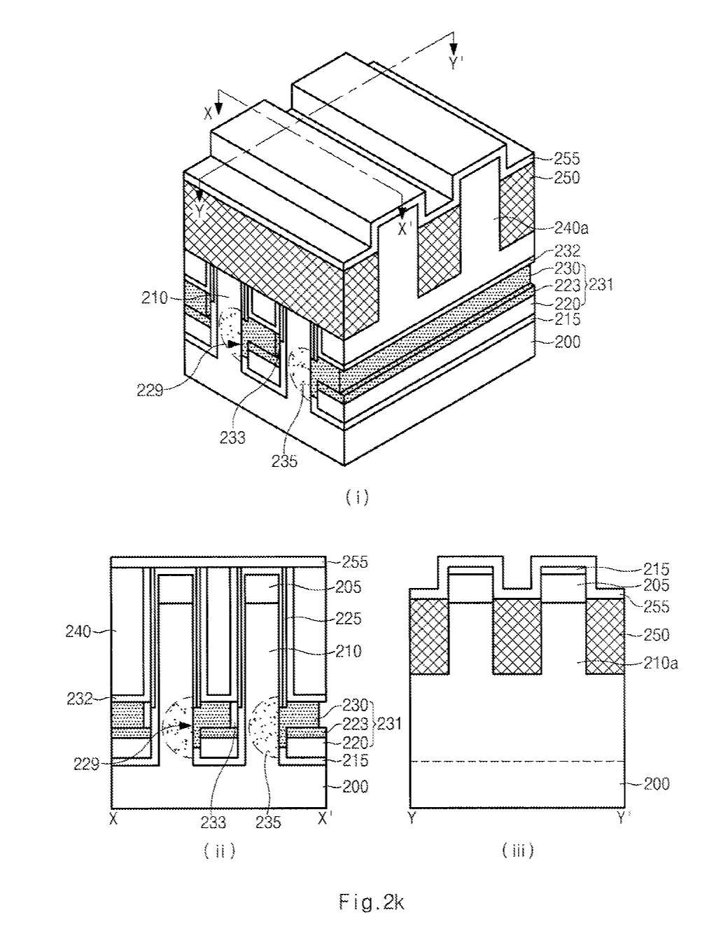

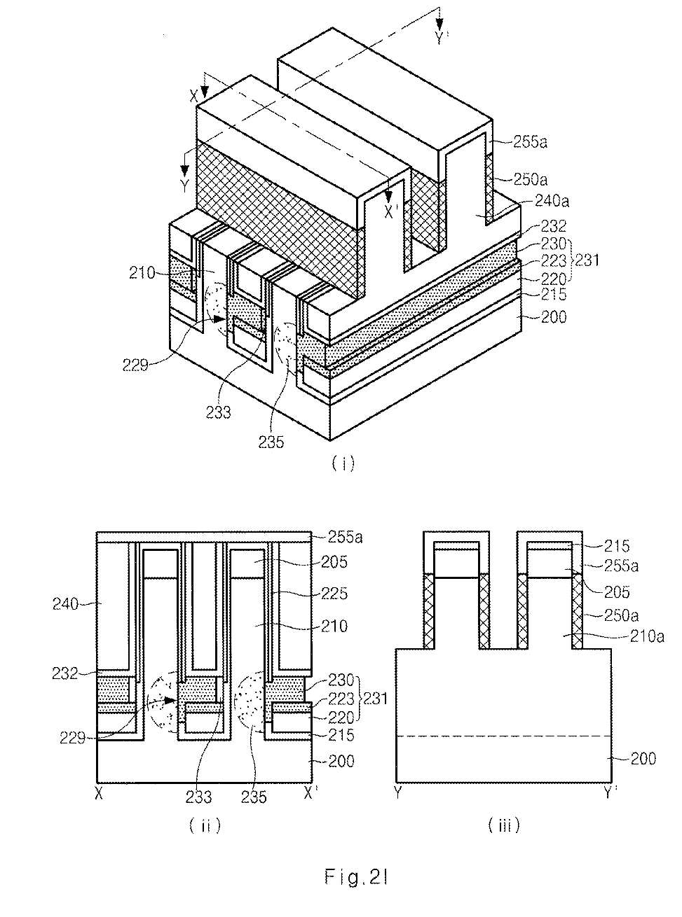

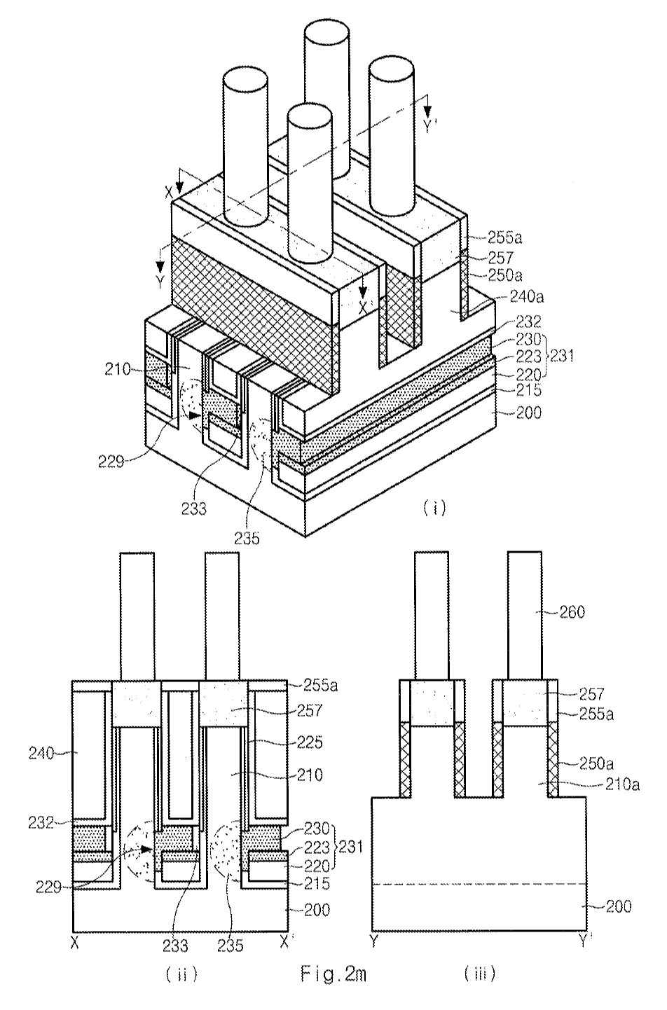

FIGS. 2A to 2M are views illustrating a method of manufacturing a semiconductor device according to an exemplary embodiment of the present invention, wherein (i) is a perspective view of a semiconductor device, (ii) is a cross-sectional view of the semiconductor device taken along the line X-X′ of (i), and (iii) are is a cross-sectional view of the semiconductor device taken along the line Y-Y′ of (i). Referring to FIG. 2A, a mask pattern 205 defining a buried bit line region is formed over a semiconductor substrate 200. The mask pattern 205 may be formed in a line shape and formed of a material including a nitride layer.

Next, the semiconductor substrate 200 is etched using the mask pattern 205 as an etch mask to form a plurality of line patterns 210. The line pattern 210 is formed to extend along the Y-Y′ direction by etching a portion of the semiconductor substrate 200. A first liner insulating layer 215 is formed over a surface of the semiconductor substrate 200 including the line patterns 210 and the mask pattern 205. The first liner insulating layer 215 may be formed of a material including an oxide layer, and a thickness of the first liner insulating layer 215 may be 80 to 120 Å.

Referring to FIG. 2B, a first bit line conduction layer 220 is formed over an entire surface of the semiconductor substrate 200 including the line patterns 210 on which the first liner insulating layer 215 is formed. The first bit line conduction layer 220 is formed to reduce resistance of the bit line. The bit line conduction layer may be formed of Ti, TiN, or a combination thereof. Subsequently, the first bit line conduction layer 220 is etched through an etching back process to be recessed in a lower portion between the line patterns 210.

Next, a second bit line conduction layer 223 is formed over the first liner insulating layer 215 and the first bit line conduction layer 220. The second bit line conduction layer 223 may include a doped polysilicon layer. Subsequently, the second bit line conduction layer 223 is etched through an etching back process to remain on the first bit line conduction layer 220 between the line patterns 210. Here, a surface level of the second bit line conduction layer 223 defines an upper level of an OSC that will be formed in a subsequent process.

Referring to FIG. 2C, a portion of the first liner insulating layer 215 exposed by the second bit line conduction layer 223, which is disposed on a sidewall of each of the line patterns 210 and an upper surface of the mask pattern 205, is removed. The removing the first liner insulating layer 215 may be performed through a cleaning process. At this time, the first liner insulating layer 215 may be etched by about a half of an originally formed thickness. For example, the first liner insulating layer 215 remaining after the cleaning process may have a thickness of 40 to 60 Å. Further, the first liner insulating layer 215 on a sidewall of the second bit line conduction layer 223 may also be partially removed according to a cleaning processing time. The first liner insulating layer 215 on the sidewall of the second bit line conduction layer 223 may be removed to a depth of 250 to 300 Å from the upper surface of the second bit line conduction layer 223.

Subsequently, a second liner insulating layer 225 is deposited over the first liner insulating layer 215 and the second bit line conduction layer 223. The second liner insulating layer 225 may be formed of a material including a nitride layer. Next, an etching back process is performed to remove a portion of the second liner insulating layer 225 disposed on the mask pattern 205 and the second bit line conduction layer 223 so that the second liner insulating layer 225 remains on a surface of the first liner insulating layer 215 which is formed over sidewalls of the line patterns 210.

Referring to FIG. 2D, an upper portion of the second bit line conduction layer 223 exposed between the line patterns 210 is etched to expose a portion of the first liner insulating layer 215 below the second liner insulating layer 225. Here, an upper surface level of the second bit line conduction layer 223 remaining after the etching process defines a lower level of the OSC that will be formed later. At this time, the second bit line conduction layer 223 should be etched uniformly to prevent the first bit line conduction layer 220 below the second bit line conduction layer 223 from being exposed.

Referring to FIG. 2E, a sacrificial conduction layer 227 is formed over surfaces of the first liner insulating layer 215, the second bit line conduction layer 223, and the second liner insulating layer 225. The sacrificial conduction layer 227 may be formed of a material including TiN. Next, an etching back process is performed to etch the sacrificial conduction layer 227 so that a portion of the sacrificial conduction layer 227 disposed on upper surfaces of the line patterns 210 and the second bit line conduction layer 223 is removed. That is, the sacrificial conduction layer 227 remains only on surfaces of the first liner insulating layer 215 and the second liner insulating layer 225 of the sidewall of each of the line patterns 210.

Next, a first insulating layer 228 is formed over the second bit line conduction layer 223 between the line patterns 210 and a planarization process is performed to expose the first liner insulating layer 215 on the upper surface of each of the line patterns 210. The first insulating layer 228 may be formed of a material including an oxide layer. For example, the first insulating layer 228 may include a spin on dielectric (SOD) layer that has a good gap-filling characteristic.

Referring to FIG. 2F, a portion of the sacrificial conduction layer 227 at the first sidewall of each of the line patterns 210 is removed, thereby exposing the first liner insulating layer 215 and the second liner insulating layer 225 at the first sidewall of each of the line patterns 210. The portion of the sacrificial conduction layer 227 at the first sidewall of each of the line patterns 210 may be removed by the following methods.

First, ions are implanted through a tilted ion implantation process in the portion of the sacrificial conduction layer 227 at the first sidewall of each of the line patterns 210, and subsequently the ion implanted portion of the sacrificial conduction layer 227 is removed using an etchant. At this time, even when the sacrificial conduction layer 227 is removed, the first bit line conduction layer 220 is not damaged because it is protected by the second bit line conduction layer 223.

Alternatively, a mask pattern exposing the portion of the sacrificial conduction layer 227 at the first sidewall of each of the line patterns 210 while covering the sacrificial conduction layer 227 at a second sidewall of each of the line patterns 210 may be formed. Then the exposed sacrificial conduction layer 227 may be removed using the mask pattern as an etch mask.

Referring to FIG. 2G, a portion of the first liner insulating layer 215 exposed by removing the sacrificial conduction layer 227 and the first insulating layer 228 are removed to expose the first sidewall of each of the line patterns 210. Thus, the exposed portion of each of the line patterns 210 becomes the OSC 229. Since the first liner insulating layer 215 and the first insulating layer 228 are formed of an oxide-based material, the first liner insulating layer 215 and the first insulting layer 228 can be simultaneously removed, and since the second liner insulating layer 225 is formed of a nitride-based material, the second liner insulating layer 225 is not removed. At this time, it is preferable that the first liner insulating layer 215 be further etched downwardly to expose the first sidewall of the second bit line conduction layer 223, as shown in “A” of FIG. 2G.

Referring to FIG. 2H, a third bit line conduction layer 230 is formed over the second bit line conduction layer 223 between the line patterns 210 including the OSCs 229. At this time, the third bit line conduction layer 230 is preferably formed to have a surface level higher than the upper portion of the OSC 229.

The first bit line conduction layer 220, the second bit line conduction layer 223 and the third bit line conduction layer 230 formed as described above are collectively called a buried bit line 231. The OSC 229 is coupled to doped polysilicon of the third bit line conduction layer 230 to reduce contact resistance. Furthermore, an electrical short between the buried bit line and a gate can be prevented when the gate is formed later.

Next, the ions are doped into the first bit line conduction layer 220 and the third bit line conduction layer 230 and then are diffused to form a bit line junction region 235 in the first sidewall of each of the line patterns 210.

Referring to FIG. 21, the sacrificial conduction layer 227 remaining at the second sidewall of each of the line patterns 210 is removed. When the sacrificial conduction layer 227 is removed, it is possible to prevent the first bit line conduction layer 220 from being removed since the first bit line conduction layer 220 is protected by the second bit line conduction layer 223. By removing the sacrificial conduction layer 227, a space is formed between the third bit line conduction layer 230 and the first liner insulating layer 215 at the second sidewall of the line patterns 210. The space is denoted as “B”.

Referring to FIG. 23, a capping layer 232 is formed over an entire surface of the semiconductor substrate 200 including the line patterns 210 and the third bit line conduction layer 230. At this time, the capping layer 232 does not fill the space B. Thereby, an air-gap 233 is formed between the third bit line conduction layer 230 and the first liner insulating layer 215. The capping layer 232 for forming the air-gap 233 may be formed of a material including a nitride layer that has a poor step coverage property.

Next, a second insulating layer 240 is formed over the entire surface of the semiconductor substrate 200 including the line patterns 210 on which the capping layer 232 is formed. The second oxide layer 240 may be formed of a material including an oxide layer. For example, the second insulating layer 240 may be preferably formed using a SOD oxide layer or a high density plasma (HDP) oxide layer as an oxide layer. More preferably, the second insulating layer 240 may be formed by stacking an SOD oxide layer and a HDP oxide layer. Subsequently, a planarization process is performed until the first liner insulating layer 215 is exposed.

Thus, the air-gap 233 and the additional insulating layer are formed at the second sidewall of the line pattern 210. The second sidewall may be located at an opposite side to the first sidewall where the OSC 229 is formed. The air-gap 233 and the additional insulating layer provide effective insulation between the buried bit line 231 and the bit line junction region 235 coupled to a neighboring buried bit line 231. Thereby, coupling capacitance between neighboring buried bit lines 231 can be prevented.

Referring to FIG. 2K, a mask pattern (not shown) defining a gate is formed over the second insulating layer 240. The mask pattern (not shown) may be formed in a line shape and formed to extend along the X-X′ direction of FIG. 1 that is perpendicular to the direction along which the buried bit line 231 is arranged.

Next, the second insulating layer 240 and upper portions of the line patterns 210 are etched using the mask pattern (not shown) as an etch mask to form pillar patterns 210a and a second insulating layer pattern 240a. At this time, the line patterns 210 and the second insulating layer 240 are etched so that the second insulating layer pattern 240a is formed on the capping layer 232. Alternatively, the line patterns 210 and the second insulating layer 240 may be etched until the capping layer 232 formed over the buried bit line 231 is exposed. A gate conduction layer 250 is formed over the semiconductor substrate 200 including the second insulating layer pattern 240a.

Next, an etch back process is performed so that the gate conduction layer 250 is formed at a lower portion between the pillar patterns 210a. A spacer material 255 is deposited on the entire surface of the semiconductor substrate 200 including the pillar patterns 210a and the gate conduction layer 250. The spacer material 255 may be formed of an oxide layer, a nitride layer, or a combination thereof, and it is preferably formed of a stack structure of a nitride layer and an oxide layer. A thickness of the spacer material 255 defines a thickness of the gate that will be formed later. See FIG. 2L.

Referring to FIG. 2L, an etching back process is performed to form spacers 255a on sidewalls of the second insulating layer pattern 240a and the pillar patterns 210a. The gate conduction layer 250 is etched using the spacers 255a as an etch mask to form a gate 250a on the sidewalls of the pillar patterns 210a and the second insulating layer pattern 240a.

Referring to FIG. 2M, the mask pattern 205, the first liner insulating layer 215 and the second liner insulating layer 225 of upper portion of the pillar pattern 210a is etched to form a storage node contact hole (not shown). A conductive material is buried in the storage node contact hole (not shown) to form a storage node contact plug 257. The conductive material may be formed of a material including a poly silicon.

a storage node junction region (not shown) is formed in an upper portion of each of the pillar patterns 210a and cylinder type storage nodes 260 are formed over the pillar patterns 210a. At this time, the storage node 260 may be formed to be connected to the storage node junction region (not shown) in the upper portion of the pillar pattern 210a.

According to the exemplary embodiment as described above, the air-gap 233 and the additional insulating layer are formed in the opposite side of the OSC 229, and thus insulation between the buried bit line 231 and the bit line junction region 235 coupled to a neighboring buried bit line 231 can be effectively accomplished. Thereby, coupling capacitance between the buried bit line 231 and a neighboring buried bit line 231 can be reduced.

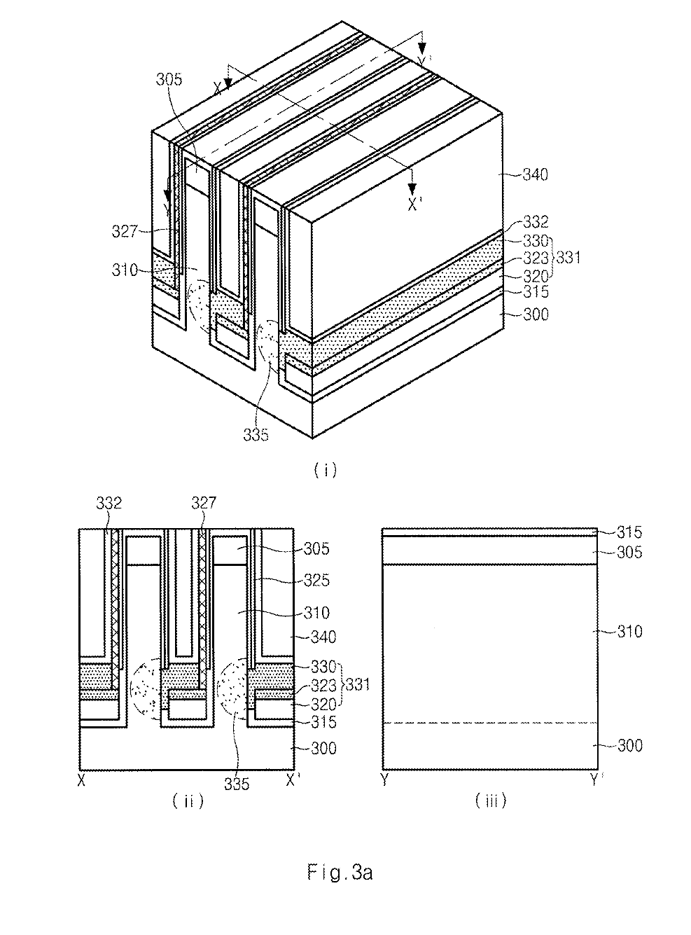

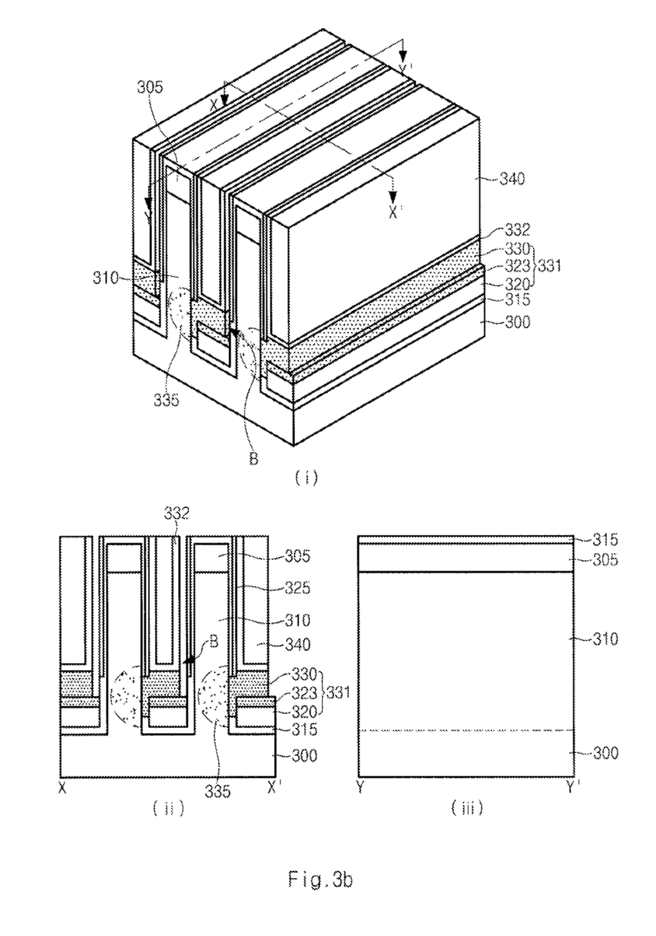

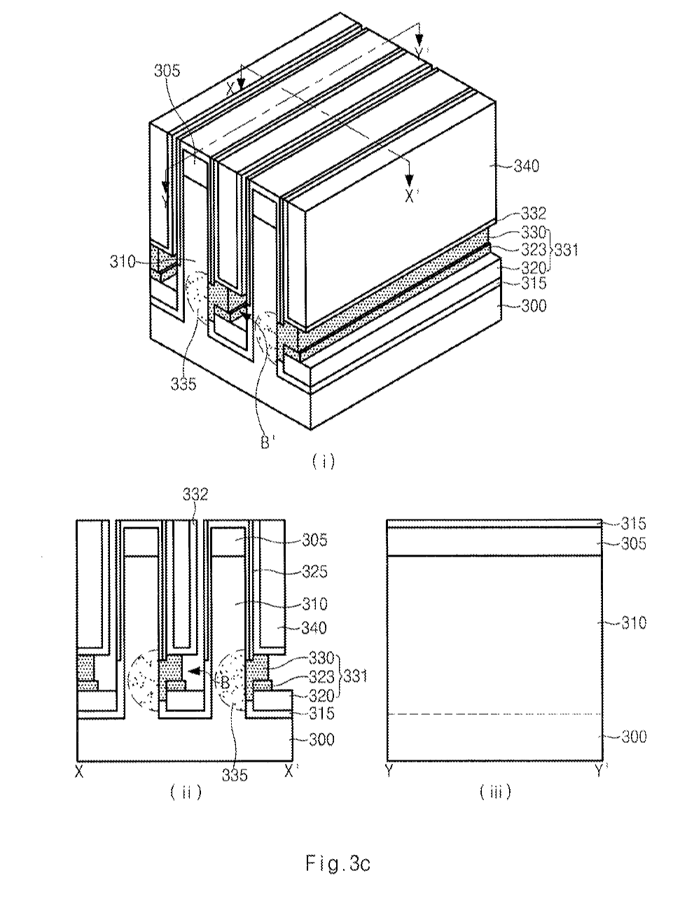

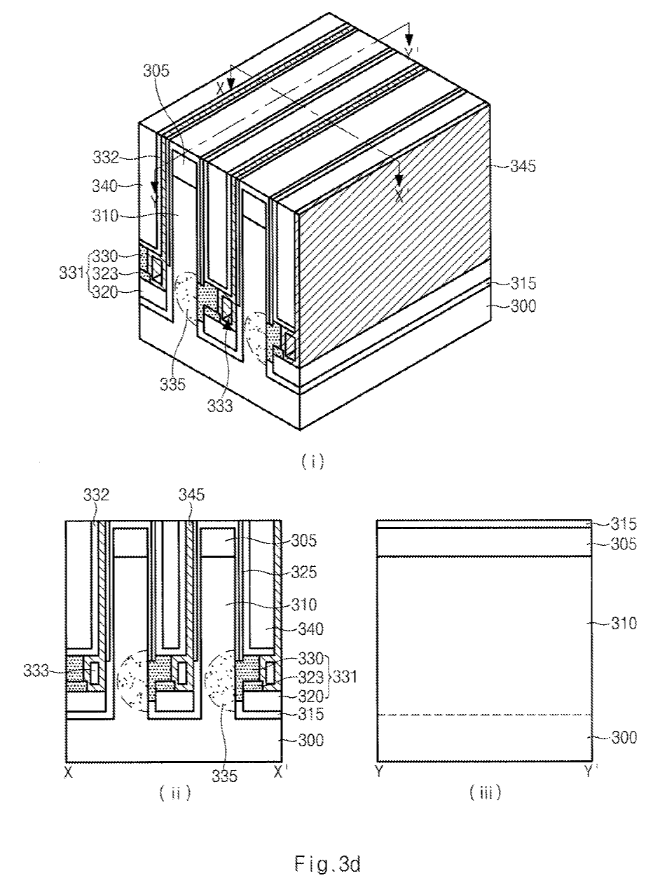

FIGS. 3A to 3D are views illustrating a method of manufacturing a semiconductor device according to another exemplary embodiment of the present invention, wherein (i) is a perspective view of a semiconductor device, (ii) is a cross-sectional view of the semiconductor device taken along the line X-X′ of (i), and (iii) is a cross-sectional view of the semiconductor device taken along the line Y-Y′ of (i). Prior to the processes shown in FIGS. 3A to 3D, a semiconductor device is obtained by the processes shown in FIGS. 2A to 2H.

Referring to FIG. 3A, ions are doped in a second bit line conduction layer 323 and a third bit line conduction layer 330, and then are diffused to form a bit line junction region 335 in a first sidewall of a line pattern 310. A capping layer 332 is formed over a surface of a semiconductor substrate 300 including the line patterns 310 and a third bit line conduction layer 330, and a second insulating layer 340 is formed over the capping layer 332. The capping layer 332 may be formed of a material including a nitride layer. The second insulating layer 340 may be formed of a material including an oxide layer. Next, a planarization process is performed until a first liner insulating layer 315 is exposed.

Referring to FIG. 3B, a sacrificial conduction layer 327 is removed to ensure an empty space “B”.

Referring to FIG. 3C, a second bit line conduction layer 323 and the third bit line conduction layer 330 exposed after the sacrificial conduction layer 327 is removed are further etched to enlarge the empty space “B”. It is preferable to prevent the bit line conduction layer from being excessively etched by controlling an etching time of the second and third bit line conduction layers 323 and 330.

Referring to FIG. 3D, an additional capping layer 345 is further deposited in the empty space B′ between the capping layer 332, the second bit line conduction layer 323 and the third bit line conduction layer 330 and each of the line patterns 310. The additional capping layer 345 is deposited over the surfaces of the second and third bit line conduction layers 323 and 330 and the first liner insulating layer 315 while leaving an empty space in the middle of the additional capping layer 345. The empty space becomes an air-gap 333.

As described above, the air-gap 333 is included in the opposite side of the OSC 229 to insulate between a buried bit line 331 and the bit line junction region 335 coupled to a neighboring buried bit line 331. Thereby, coupling capacitance between neighboring buried bit lines 331 can be reduced.

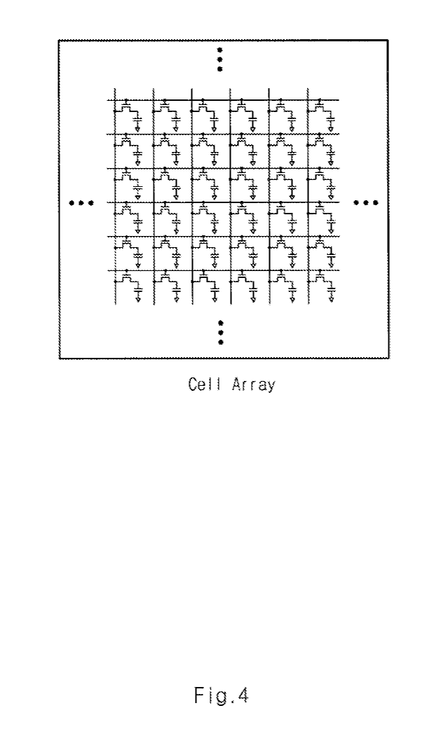

FIG. 4 is a circuit diagram illustrating a semiconductor cell array including the above-described exemplary embodiments of the present invention.

Typically, the semiconductor cell array includes a plurality of memory cells and each memory cell includes one transistor and one capacitor. Such semiconductor cells are disposed at intersections of bit lines BL1, . . . , BLn and word lines WL1, . . . , WLm. The semiconductor cells store and output data based on voltages applied to the bit lines BL1, . . . , BLn and the word lines WL1, . . . , WLm selected by a column decoder and a row decoder.

As shown in FIG. 4, in the semiconductor cell array, the bit lines BL1, . . . , BLn are formed to extend in a first direction (bit line direction) and the word lines WL1, . . . , WLm are formed to extend in a second direction (word line direction) so that the bit lines BL1, . . . , BLn and the word lines WL1, . . . , WLm are disposed to intersect each other. A first terminal (for example, a drain terminal) of the transistor is connected to the bit line BL1, . . . , BLn, a second terminal (for example, a source terminal) is connected to a capacitor, and a third terminal (for example, a gate terminal) is connected to a word line WL1, . . . , WLm. A plurality of semiconductor cells including the bit lines BL1, . . . , BLn and word lines WL1, . . . , WLm are disposed within the semiconductor cell array.

In an embodiment, the bit line is formed as illustrated in FIG. 1. One side of the bit line may be connected to the bit line junction region and the bit line may include the air-gap formed between the other side thereof and the line pattern. The bit line may be formed to have a structure where an insulating layer is disposed within the air-gap.

As described above, the semiconductor cell array according to the exemplary embodiment can reduce coupling capacitance between the bit lines and thus improve characteristics of the devices.

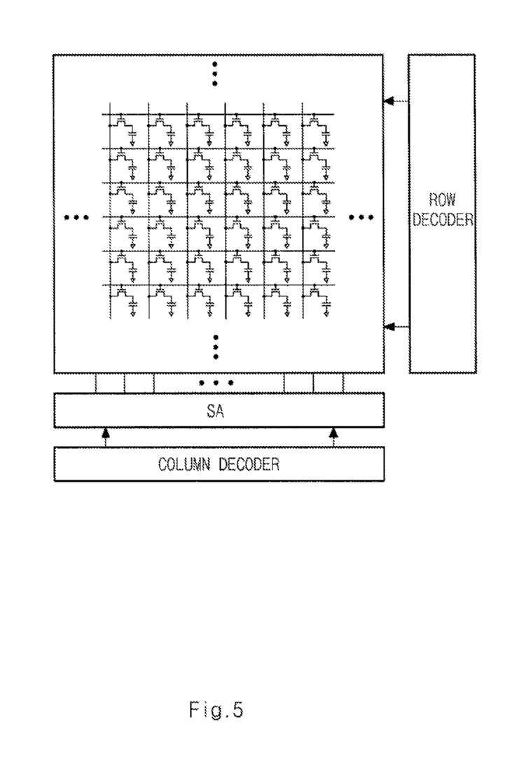

FIG. 5 is a block diagram illustrating a semiconductor device according to an exemplary embodiment of the present invention.

Referring to FIG. 5, the semiconductor device may include a semiconductor cell array, a row decoder, a column decoder, and a sense amplifier. The row decoder selects a word line corresponding to a semiconductor cell in which a read or write operation is to be performed and outputs a word line select signal (RS) to the semiconductor cell array. The column decoder selects a bit line corresponding to a semiconductor cell in which a read or write operation is to be performed array and outputs a bit line select signal (CS) to the semiconductor cell array. Further, the sense amplifier senses data stored in a semiconductor cell selected by the row decoder and a column decoder.

In an embodiment, the bit line is formed as illustrated in FIG. 1. One side of the bit line may be connected to the bit line junction region and the bit line may include the air-gap formed between the other side thereof and the line pattern. The bit line may be formed to have a structure where an insulating layer is buried within the air-gap. As described above, the semiconductor cell array according to the exemplary embodiment can reduce coupling capacitance between the bit lines and thus improve characteristics of the devices.

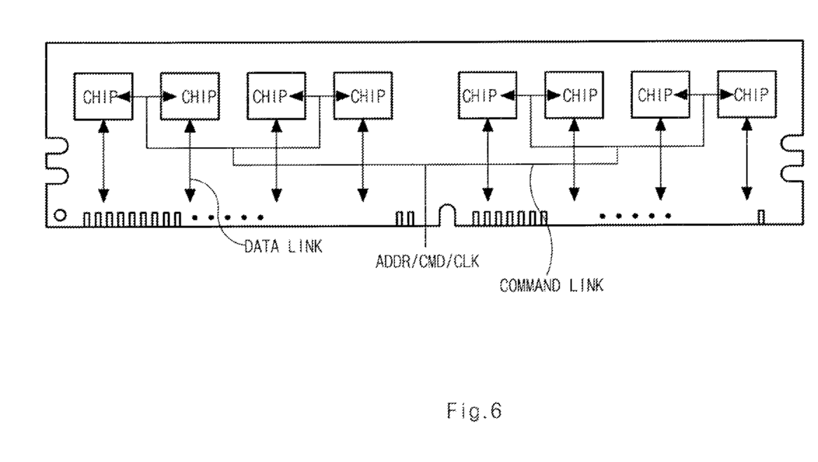

FIG. 6 is a block diagram illustrating a semiconductor module according to an exemplary embodiment of the present invention.

Referring to FIG. 6, the semiconductor module includes a plurality of semiconductor devices mounted on a module substrate, a command link which allows the semiconductor device to receive control signals (address signal (ADDR), a command signal (CMD), a clock signal (CLK)) from an external controller (not shown), and a data link which is connected to the semiconductor devices and transfers data to the semiconductor devices.

Here, the command link and the data link can be the same or similar to those that are used in a conventional semiconductor module.

Although FIG. 6 illustrates 8 semiconductor devices mounted on a front of the semiconductor module, additional semiconductor devices may also be mounted on a rear of the module in the same manner. That is, semiconductor devices may be mounted on one side or both sides of a module substrate and the number of semiconductor devices is not limited to eight on each side. In addition, material and construction of the module substrate are not limited to the exemplary embodiment shown in FIG. 6.

A bit line formed within such a semiconductor module is formed as illustrated in FIG. 1. One side of the bit line may be connected to the bit line junction region, and the bit line may include the air-gap formed between the other side thereof and the line pattern. The bit line may be formed to have a structure where an insulating layer is buried within the air-gap.

As described above, a semiconductor cell array according to an exemplary embodiment can reduce coupling capacitance between bit lines, and thus improve characteristics of the devices.

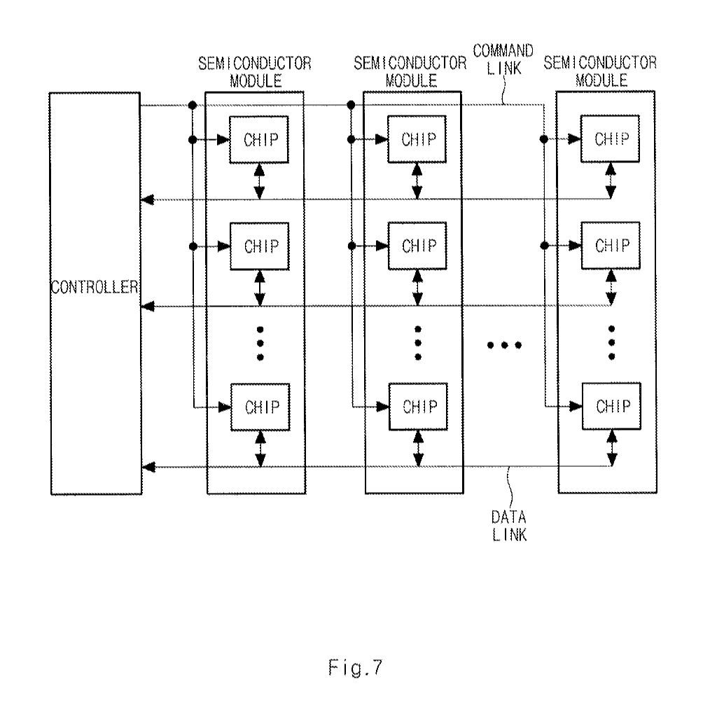

FIG. 7 is a block diagram illustrating a semiconductor system according to an exemplary embodiment of the present invention.

Referring to FIG. 7, the semiconductor system includes a semiconductor module including one or more semiconductor devices. The semiconductor system includes a memory controller that communicates data and command/address signals with the semiconductor module through a system bus.

In an embodiment, the bit line formed within the semiconductor device of the semiconductor system is formed as illustrated in FIG. 1. One side of the bit line may be connected to the bit line junction region and the bit line may include the air-gap formed between the other side thereof and the line pattern. At this time, the bit line may be formed to have a structure where an insulating layer is buried within the air-gap.

As described above, a semiconductor cell array according to an embodiment of the present invention can reduce coupling capacitance between the bit lines and thus improve characteristics of the devices.

The semiconductor device according to an embodiment of the present invention may be applied to dynamic random access memories (DRAMs), but it is not limited thereto. For example, it may be applied to static random access memories (SRAMs), flash memories, ferroelectric random access memories (FeRAMs), magnetic random access memories (MRAMs), and phase change random access memories (PRAMs).

Embodiments of the present invention can be applied to a variety of electronic devices including desktop computers, portable computers, computing memories used in servers, graphics memories having various specs, and mobile device memories. Furthermore, the above-described semiconductor device may be provided to various digital applications such as mobile recording mediums including a memory stick, multimedia card (MMC), secure digital (SD), compact flash (CF), extreme digital (xD) picture card, and a universal serial bus (USB) flash device, as well as various digital applications such as MP3P, portable multimedia player (PMP), a digital camera, a camcorder, and a mobile phone. A single semiconductor device may be applied to a technology such as multi-chip package (MCP), disk on chip (DOC), or an embedded device. The single semiconductor device may be applied to a CMOS image sensor (CIS) provided to various fields such as a camera phone, a web camera, a small-size image pick-up device for medicine.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

1. A semiconductor device, comprising:
a plurality of line patterns, each line pattern including a one side contact (OSC) formed at a first sidewall of each line pattern;
a bit line buried in a lower portion of the device between neighboring line patterns;
a bit line junction region formed within each of the line patterns and coupled to the bit line through the one side contact (OSC); and
an air-gap formed between a second sidewall of the line pattern and a neighboring bit line.

2. The semiconductor device of claim 1, wherein the line patterns include etched portions of a semiconductor substrate.

3. The semiconductor device of claim 1, the device further comprising a liner insulating layer disposed over surfaces of the line patterns.

4. The semiconductor device of claim 1, wherein the bit line includes at least one layer selected from the group consisting of a titanium layer, a titanium nitride layer, and a doped polysilicon layer.

5. The semiconductor device of claim 1, the device further comprising:
an insulating layer (345 in FIG. 3d) formed to surround the air-gap.

6. The semiconductor device of claim 1, the device further comprising:
a capping layer (232 in FIG. 2J) disposed over the bit line and the air-gap.

7. The semiconductor device of claim 6, wherein the capping layer includes a nitride layer.

8. A semiconductor cell, comprising:
a transistor including a gate and a storage node junction region;
a bit line arranged to intersect the gate;
a bit line contact coupling a bit line junction region to the bit line; and
an air-gap formed between a sidewall of line pattern and a neighboring the bit line and a line pattern.

9. The semiconductor cell of claim 8, the semiconductor cell further comprising:
a storage unit coupled to the storage node junction region.

10. The semiconductor cell of claim 9, wherein the storage unit includes a capacitor.

11. The semiconductor cell of claim 8, wherein the gate is a vertical gate formed on at least two sides of a pillar pattern that extends across the line patterns.

12. The semiconductor cell of claim 8, wherein the bit line includes at least one selected from the group consisting of a titanium layer, a titanium nitride layer, and a doped polysilicon layer.

13. The semiconductor cell of claim 8, wherein the air-gap is formed over a sidewall of the bit line.

14. The semiconductor cell of claim 8, the semiconductor cell further comprising:
an insulating layer is buried within the air-gap.

15. A semiconductor chip, comprising:
a core circuit area; and
a semiconductor cell of claim 8.

16. The semiconductor chip of claim 15, wherein the core circuit area includes:
a row decoder which selects word line of the semiconductor cell array;
a column decoder which selects bit line of the semiconductor cell array; and
a sense amplifier which senses data stored in a semiconductor cell selected by the row decoder and the column decoder.

17. A semiconductor module, comprising:
a semiconductor chip of claim 15; and
an external input/output (I/O) line coupled to the semiconductor chip.

18. The semiconductor module of claim 17, the semiconductor module further comprising:
a data input buffer;
a command/address input buffer; and
a resistor unit.

19. The semiconductor module of claim 18, the module further comprising:
an internal command/address bus configured to transmit a command/address signal to the command/address input buffer.

20. A semiconductor system, comprising:
a semiconductor module of claim 17; and
a controller configured to communicate with the semiconductor module to transmit data and a command/address signal to or from the semiconductor module.

21-31. (canceled)
